(19) United States
(12) Patent Application Publication
(10) Pub. No.: US 2009/0032834 A1
(43) Pub. Date: Feb. 5, 2009

(54) HIGHLY EFFICIENT LED WITH MICROCOLUMN ARRAY EMITTING SURFACE

(76) Inventor: Zhengbiao OUYANG, Shenzhen (CN)

Correspondence Address: MATTHIAS SCHOLL, 14781 MEMORIAL DRIVE, SUITE 1319, HOUSTON, TX, 77079, US

(21) Appl. No.: 12/174,059

(22) Filed: Jul. 16, 2008

(30) Foreign Application Priority Data
Jul. 31, 2007 (CN) 200710075440.3

(51) Int. Cl. H01L 33/00

(52) U.S. Cl. 257/103; 257/E33.025

(57) ABSTRACT

A highly efficient light emitting diode with microcolumn array emitting surface, wherein the microcolumn array is prepared on the emitting surface of the light emitting diode, and can be formed with a two-dimensional periodic or non-periodic structure, the length and height of each microcolumn are in the same order of magnitude as, more specifically are from half to a few of, the wavelength of the emitting light. This invention utilizes a strong diffraction effect of the microcolumn array to increase the luminous efficiency of the light emitting diode. The distribution of light emitting is uniform. Compared with the conventional two-dimensional photonic crystal light emitting diode, the manufacturing process of this invention is simple, and the manufacturing cost is low. Compared with the conventional porous surface light emitting diode, the luminous efficiency of the light emitting diode according to this invention is high.

### CROSS-REFERENCE TO RELATED APPLICATIONS

Pursuant to 35 U.S.C § 119 and the Paris Convention Treaty, this application claims the benefit of Chinese Patent Application No. 200710075440.3 filed Jul. 31, 2007, the contents of which are incorporated herein by reference.

### BACKGROUND OF THE INVENTION

1. Field of the Invention

The invention relates to a highly efficient light emitting diode (LED), and more particularly, to a light emitting microcolumn array structure for improving the luminous efficiency of LED.

2. Description of the Related Art

Improvement of the luminous efficiency of light emitting diode (LED) constitutes an important research focus in the field of LED technology. When light from a point light source propagates through a medium having a certain length, only a portion of the light within a certain emitting angle is emitted out and the remaining portion is reflected at the air-medium interface. This is a serious limitation of the luminous efficiency of LEDs. In respect to this problem, methods utilizing microstructure theory are applied to improve light emitting direction so as to increase the luminous efficiency.

For example, as described in China Pat. No. CN1874012A, the LED surface can be made more porous to increase the emitting area and thus to increase the light interface in the emitting medium. However, although the luminous efficiency of LED can be increased to a certain extent, the light out of the limit emitting angle can not be utilized fully owing to the interface total reflection. In an additional method described in China Pat. No. CN1877872A, the forbidden band characteristic of a two-dimensional photonic crystal can be utilized as reflection barrier to limit the light emitting direction. However, due to the existence of a photonic crystal trap, only the bundle of light at the central micro-region of the emitting surface can be emitted out efficiently, and light at other emitting surfaces is not emitted out effectively, resulting in a small effective light emitting area. Moreover, the diameter and height of the cylinders and the distance between two adjacent cylinders in a two-dimensional photonic crystal are required to be less than half of the operating wavelength, which complicates the manufacturing process and increases manufacturing costs.

### SUMMARY OF THE INVENTION

A microcolumn array structure is applied in this invention. By utilizing diffraction theory, a microcolumn array is designed according to the light source wavelength of LED so that the emitting light is emitted out efficiently. Thus, the emitting light can be utilized fully and the uniformity of emitting light on the whole emitting surface of LED is ensured. As remarkable feature of the microcolumn array structure of this invention, the diameter and height of microcolumn and the distance between the microcolumns are in the same order of magnitude as the wavelength of the emitting light (more specifically, they are from half to a few wavelengths of the emitting light), and the arrangement of the microcolumns is not necessarily periodic, so that the process complexity and manufacturing cost is decreased.

When the diameter and height of the microcolumn are in the same order of magnitude as the wavelength, geometrical optics does not play a leading role, and a strong diffraction effect can be produced, so that the light can propagate through the microcolumn array via diffraction. Therefore, the luminous efficiency is improved. Optionally, the microcolumn can also be understood as an emitting antenna the length of which is in the same order of magnitude as the wavelength. According to the wavelength propagation theory, this kind of antenna offers high radiation efficiency, which also helps to explain the increase of the luminous efficiency increase of the LED. On the other hand, the existence of a plurality of micropores decreases largely the effective dielectric constant of the emitting area, so that the emitting angle is increased largely. Therefore, the light reflection is decreased and the luminous efficiency is increased.

From the standpoint of light interference, if the light produced by LED is similar to coherent light, application of periodic arranged structure contributes to improve the luminous efficiency. However, since the light produced by LED is normally incoherent, it is not necessary that the microcolumns are periodically arranged, and the luminous efficiency will not be influenced. Therefore, the arrangement of microcolumns can be non-periodic.

Therefore, a microcolumn array is applied in LED manufacturing in accordance with this invention, and the luminous efficiency is improved by utilizing the light diffraction in the microcolumn array.

### BRIEF DESCRIPTION OF THE DRAWINGS

FIG. 1 is a cross sectional view of a LED with microcolumn array structure according to one embodiment of this invention, in which the microcolumn arrays are connected to each other via sidewalls;

FIG. 2 is a planar view of a LED with microcolumn array structure according to one embodiment of this invention, in which the microcolumn arrays are connected to each other via sidewalls;

FIG. 3 is a cross-sectional view of a LED with microcolumn array structure according to one embodiment of this invention, in which the microcolumn arrays are connected to each other via bottom surfaces;

FIG. 4 is a planar view of a LED with microcolumn array structure according to one embodiment of this invention, in which the microcolumn array is connected to each other via bottom surfaces;

FIG. 5 is a planar view illustrating a hexagon shaped cross section of a microcolumn array according to one embodiment of this invention; and

FIG. 6 is a planar view illustrating a non-periodic arranged microcolumn array according to one embodiment of this invention.

The reference numbers of the various parts shown in the drawings are listed below, in which sapphire substrate corresponds to the number 1; buffer layer—2; N-type GaN layer—3; active layer—4; microcolumn array on P-type GaN layer—5; P-type electrode—6; and N-type electrode—7.

### DETAILED DESCRIPTION OF THE INVENTION

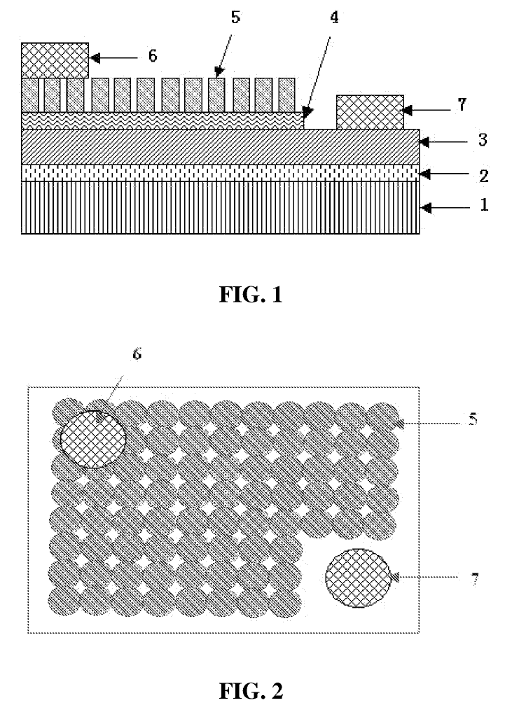

FIG. 1 shows a basic structure of an LED, comprising: a sapphire substrate 1; a buffer layer 2; a N-type GaN layer 3 grown on the buffer layer 2 of the sapphire substrate 1; an active GaN layer 4 grown on the N-type GaN layer 3; a P-type GaN layer 5 prepared on the active layer 4 and etched with microcolumn array; a P-type transparent electrode and P-type bonding pad 6 laid on the P-type GaN layer 5; and a N-type transparent electrode and N-type bonding pad 7 laid on the N-type GaN layer 3.

FIG. 2 illustrates a planar structure of an LED, wherein the solid circle represents medium column, namely, forming the microcolumn array 5.

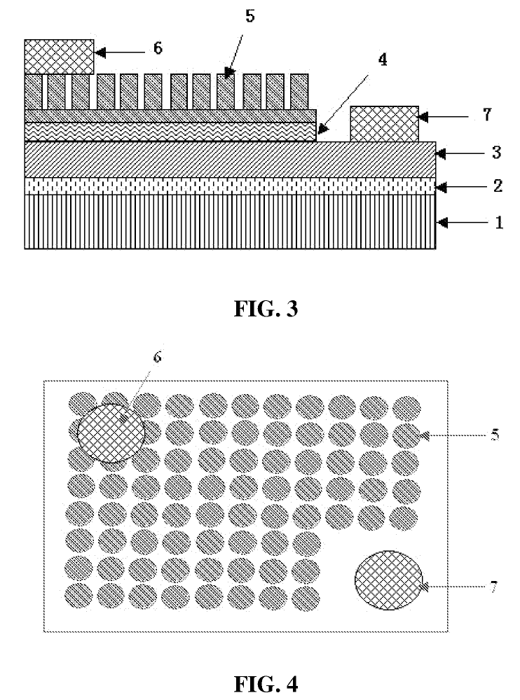

In certain embodiments of this invention, the microcolumn array 5 is formed in a way that the etching depth L of the microcolumn passes fully through the N-type GaN layer 3. Namely, the microcolumns are connected to each other via sidewalls, as illustrated in FIGS. 1-2. Alternatively, the microcolumn array 5 is formed in a way that the etching depth L of the microcolumn does not pass fully through the N-type GaN layer 3, namely, the microcolumns are separated to each other and are connected to each other via bottom surfaces, as illustrated in FIGS. 3-4.

In certain embodiments of this invention, the diameter and height of a single microcolumn of the microcolumn array 5, the distance between microcolumns, and the wavelength of the emitting light are in the same order of magnitude.

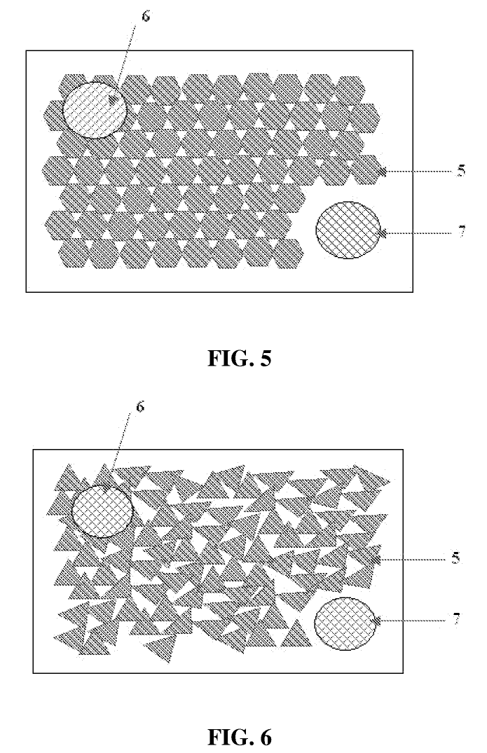

In certain embodiments of this invention, the microcolumn array 5 is formed generally by means of etching technology, the cross section can be in a shape of circle, triangle, rectangle, hexagon, or other polygons, or a combination of these polygons, as illustrated in FIGS. 4-6.

In certain embodiments of this invention, the microcolumn array 5 has a two-dimensional periodic or non-periodic arranged structure, as illustrated in FIG. 6.

In certain embodiments of this invention, the microcolumn array structure of this invention is not only suitable for improving the luminous efficiency of sapphire substrate based GaN LED, but also applicable for other type LED sources.

As a result, this invention provides the following advantages:
1) The luminous efficiency of LED is increased effectively. Since the design of this invention makes the most of light diffraction technology in the microcolumn array, the emitting light is emitted out efficiently, the light produced by the LED is fully utilized, and thus the luminous efficiency of LED is increased to a certain extent. Compared with conventional porous surface LED, the luminous efficiency of the LED of this invention is increased greatly.
2) The manufacturing process is simple, and the process complexity is decreased. The arrangement of microcolumns is not required to be periodic as long as it is uniformly distributed. The diameter and the height of microcolumn and the distance between microcolumns are generally smaller than the wavelength of the emitting light, or are in the same order of magnitude of the wavelength of the emitting light. As compared to a two-dimensional photonic crystal microstructure on the LED surface especially for blue LED application, the process complexity is decreased.
3) The light emitting is uniform, and the utilization rate of light emitting area is high. The entire top surface is comprised of uniformly distributed microcolumns, and this contributes to an increase of the utilization rate of light emitting surface area and ensures the uniform distribution of light emitting surface. The emitting light produced from the LED is very uniform. Compared to conventional two-dimensional photonic crystal structured LED, the light emitting effective area and light emitting planar uniformity are improved greatly.
4) This invention is not only suitable for the production of GaN-based blue LEDs, but also applicable for the production of other material based semiconductor LEDs and organic LEDs applied in other wavelength bands.

The method of production of LEDs described herein comprises: (a) depositing GaN buffer layer first on a sapphire substrate 1, and then growing LED epitaxial wafer thereon; (b) using mask process technology, etching microcolumn array on a P-type GaN layer 5 via photo etching and dry etching technology; and (c) preparing electrode 7 on an N-type GaN layer, and making N-type bonding pad on the electrode 7; preparing electrode 6 on a P-type GaN layer, and making P-type bonding pad on the electrode 6. The electrode can be transparent electrode, or normal structure metal electrode, or normal metal electrode with complicated pattern or shape. The electrode is laid on the entire GaN layer.

This invention is not to be limited to the specific embodiments disclosed herein and modifications for various applications and other embodiments are intended to be included within the scope of the appended claims. While this invention has been described in connection with particular examples thereof, the true scope of the invention should not be so limited since other modifications will become apparent to the skilled practitioner upon a study of the drawings, specification, and following claims.

All publications and patent applications mentioned in this specification are indicative of the level of skill of those skilled in the art to which this invention pertains. All publications and patent applications mentioned in this specification are herein incorporated by reference to the same extent as if each individual publication or patent application mentioned in this specification was specifically and individually indicated to be incorporated by reference.

What is claimed is:

1. A light emitting diode comprising a two-dimensional microcolumn array, wherein said two-dimensional microcolumn array is etched on the surface of a P-type GaN layer.

2. The light emitting diode of claim 1, wherein the cross section of said two-dimensional microcolumn array is in the shape of a circle, a triangle, a square, a hexagon, or a combination of polygons.

3. The light emitting diode of claim 1, wherein said two-dimensional microcolumn array is periodic or non-periodic.

4. The light emitting diode of claim 1, wherein
said two-dimensional microcolumn array comprises a plurality of microcolumns, and
the diameter and/or the height of said microcolumns and the distance between microcolumns of the microcolumn array are in the same order of magnitude as the wavelength of light emitted by the light emitting diode.

5. The light emitting diode of claim 4, wherein the diameter and/or the height of said microcolumns and the distance between microcolumns of the microcolumn array are from a half to a few wavelengths of light emitted by the light emitting diode.
